(19) United States
(12) Patent Application Publication
(10) Pub. No.: US 2007/0096143 A1
(43) Pub. Date: May 3, 2007

(54) Nitride semiconductor light emitting device and method for manufacturing the same

(75) Inventors: Sun Woon Kim, Seoul (KR); Je Won Kim, Suwon (KR); Pil Geun Kang, Suwon (KR); Keun Man Song, Seoul (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD

(21) Appl. No.: 11/517,337

(22) Filed: Sep. 8, 2006

(30) Foreign Application Priority Data
Sep. 8, 2005 (KR) 10-2005-0083726

(51) Int. Cl. H01L 33/00; H01L 29/24

(52) U.S. Cl. 257/103

(57) ABSTRACT

The invention relates to a nitride semiconductor light emitting device having a high light emission efficiency, low operating voltage and high resistance to electrostatic discharge. The nitride semiconductor light emitting device includes an n-type nitride semiconductor layer, an active layer and a p-type nitride semiconductor layer formed in their order on a substrate. The device also includes a transparent conductive oxide multi-layer formed on the p-type nitride semiconductor layer. The transparent conductive oxide multi-layer includes two or more layers or transparent conductive oxide layers having different levels of conductivity.

### CLAIM OF PRIORITY

This application claims the benefit of Korean Patent Application No. 2005-83726 filed on Sep. 8, 2005, in the Korean Intellectual Property Office, the disclosure of which is incorporated herein by reference.

### BACKGROUND OF THE INVENTION

1. Field of the Invention

The present invention relates to a nitride semiconductor light emitting device, and more particularly, to a nitride semiconductor light emitting device having high light emission efficiency while having low operating voltage and high resistance to Electrostatic Discharge (ESD).

2. Description of the Related Art

Recently, light emitting diodes (LEDs) or laser diodes (LDs) using group III-V nitride semiconductors (or simply nitride semiconductors) are extensively adopted in light emitting devices to obtain light in blue or green wavelength range and applied to various products such as display boards, illumination apparatuses, etc. as light sources therefor. The group III-V nitride semiconductors are typically made of GaN-based material having a composition of InₓAl_{y}Ga_{(1-x-y)}N, where 0≦x≦1, 0≦y≦1 and 0≦x+y≦1. In order to manufacture such a nitride semiconductor light emitting device, it is critical to form a good ohmic contact between the p-electrode and p-type nitride semiconductor. In U.S. Pat. No. 5,563,422, Ni/Au is used for a layer for an ohmic contact with a p-type nitride semiconductor. However, the Ni/Au layer has a low light transmittance, thus degrading overall light emission efficiency.

FIG. 1 is a sectional view illustrating a conventional nitride semiconductor light emitting device. Referring to FIG. 1, the conventional nitride light emitting device 10 includes a GaN buffer layer 12, an n-type GaN-based clad layer 13, an active layer of single quantum well or multiple quantum well structure of InGaN/GaN and a p-type GaN-based clad layer 15 sequentially formed on a sapphire substrate 11. An n-electrode 21 is formed on a portion of an upper surface of the n-type GaN-based clad layer 13 exposed by mesa etching. In order for an ohmic contact with the p-type GaN semiconductor, a transparent electrode 18 made of Ni/Au is formed between the p-type GaN-based clad layer 15 and the p-electrode pad 22. The transparent electrode 18 serves to lower a forward voltage by increasing a current injection area and forming the ohmic contact. However, the transparent electrode 18 made of Ni/Au has a low light transmittance of about 60% in the wavelength range of light generated from the active layer 14, thus resulting in low light emission efficiency.

To overcome such a problem, U.S. Pat. No. 6,693,352 suggests using an Indium Tin Oxide (ITO)-based transparent conductive oxide layer having a transmittance of about at least 90% as a transparent p-electrode (see FIG. 2). Still however, the ITO transparent electrode does not form a good ohmic contact with the p-type nitride semiconductor, thus adversely increasing the operating voltage. In addition, U.S. Pat. No. 6,818,467 discloses that a metal layer of Ni, Au, etc. can be formed between an ITO layer and a p-type nitride semiconductor to ensure good light transmittance and improve the ohmic contact characteristics with the p-type nitride semiconductor. The graph in FIG. 2 shows light transmittance of various materials. As shown in FIG. 2, an ITO/Ni layer has a transmittance in the range between ITO and Ni/Au.

However, according to the above-described conventional technologies, current tends to concentrate in the region where a p-side bonding electrode is formed, causing non-uniform light emission characteristics. Also, due to the locally concentrated current, the light emitting device is vulnerable to ESD. Therefore, in order to realize a light emitting device having a superior capacity, both the operating voltage characteristics and light emission efficiency need to be improved.

### SUMMARY OF THE INVENTION

The present invention has been made to solve the foregoing problems of the prior art and therefore an object of certain embodiments of the present invention is to provide a nitride semiconductor light emitting device having improved light emission efficiency, operating voltage characteristics and resistance to ESD due to a current spreading effect.

Another object of certain embodiments of the invention is to provide a method of manufacturing a nitride semiconductor light emitting device that can improve light emission efficiency, operating voltage characteristics and resistance to ESD thereof.

According to an aspect of the invention for realizing the object, there is provided a nitride semiconductor light emitting device including: an n-type nitride semiconductor layer, an active layer and a p-type nitride semiconductor layer sequentially formed on a substrate; and a transparent conductive oxide multi-layer formed on the p-type nitride semiconductor layer, wherein the transparent conductive oxide multi-layer includes two or more transparent conductive oxide layers having different levels of conductivity.

According to an embodiment of the present invention, the transparent conductive oxide layers may be made of at least one selected from a group consisting of ITO, ZnO, MgO and InO.

According to the present invention, the transparent conductive oxide layers may have different levels of conductivity according to different oxygen vacancy densities or compositions. For example, the transparent conductive oxide layers may be ITO layers and the conductivity of the ITO layers may be adjusted by oxygen vacancy densities or Sn contents.

According to an embodiment of the present invention, the transparent conductive oxide multi-layer may comprise a plurality of layer groups stacked repeatedly two or more times, each of the layer groups consisting of two or more transparent conductive oxide layers having different levels of conductivity.

According to a preferred embodiment of the present invention, the transparent conductive oxide multi-layer may include a stacked structure of first, second and third oxide layers, and the second oxide layer may have a lower level of conductivity than the first and third oxide layers. Also, the second oxide layer may have a higher level of conductivity than the first and third oxide layers. More preferably, the transparent conductive oxide multi-layer may include a stacked structure of high-conductivity, low-conductivity and high-conductivity layers or a stacked structure of low-conductivity, high-conductivity and low-conductivity layers.

According to an embodiment of the present invention, the transparent conductive oxide multi-layer includes a plurality of three-layer structures stacked repeatedly, each of the three-layer structures having first, second and third oxide layers. In this case, the second oxide layer may have a lower level of conductivity than the first and third oxide layer, and the first and third layers have different levels of conductivity from each other.

In addition, the transparent conductive oxide multi-layer includes a plurality of three-layer structures stacked repeatedly, each of the three-layer structures having first, second and third oxide layers. In this case, the second oxide layer may have a higher level of conductivity than the first and third oxide layers, and the first and third oxide layers have different levels of conductivity from each other.

According to an embodiment of the present invention, the nitride semiconductor light emitting device may further comprise a contact metal layer between the p-type nitride semiconductor layer and the transparent conductive oxide multi-layer. The contact metal layer may be made of at least one selected from a group consisting of Ni, Au, Pt and Pd. The contact metal layer functions to further enhance ohmic contact characteristics with the p-type nitride semiconductor layer.

According to another aspect of the invention for realizing the object, there is provided a method of manufacturing a nitride semiconductor light emitting device including steps of:

sequentially forming an n-type nitride semiconductor layer, an active layer and a p-type nitride semiconductor layer on a substrate; and

forming a transparent conductive oxide multi-layer which includes two or more transparent conductive oxide layers having different levels of conductivity on the p-type nitride semiconductor layer.

According to an embodiment of the present invention, the transparent conductive oxide layers may be made of at least one selected from a group consisting of ITO, ZnO, MgO and InO.

According to the present invention, in the step of forming the transparent conductive oxide multi-layer, the transparent conductive oxide layers having different oxygen vacancy densities or compositions may be stacked. For example, ITO layers having different oxygen vacancy densities or different Sn contents may be stacked. The oxygen vacancy density may be adjusted by oxygen partial pressure at the time of forming the transparent conductive oxide layers.

According to a preferred embodiment of the present invention, the step of forming the transparent conductive oxide multi-layer may include forming a stacked structure of first, second and third oxide layers (the second oxide layer has a lower level of conductivity than the first and third oxide layers). In addition, the step of forming the transparent conductive oxide multi-layer may include forming a stacked structure of first, second and third oxide layers (the second oxide layer has a higher level of conductivity than the first and third oxide layers).

According to an embodiment of the present invention, the step of forming the transparent conductive oxide multi-layer may comprise repeatedly stacking a plurality of three-layer structures each consisting of first, second and third oxide layers (the second oxide layer has a lower level of conductivity than the first and third oxide layers, and the first and third oxide layers have different levels of conductivity from each other).

In addition, the step of forming the transparent conductive oxide multi-layer comprises repeatedly stacking a plurality of three-layer structures each consisting of first, second and third oxide layers (the second oxide layer has a higher level of conductivity than the first and third oxide layers, and the first and third oxide layers have different levels of conductivity from each other).

According to an embodiment of the present invention, a contact metal layer may be formed on the p-type nitride semiconductor layer before the step of forming the transparent conductive oxide multi-layer. The contact metal layer may be made of at least one selected from a group consisting of Ni, Au, Pt and Pd.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a sectional view illustrating a conventional nitride semiconductor light emitting device;

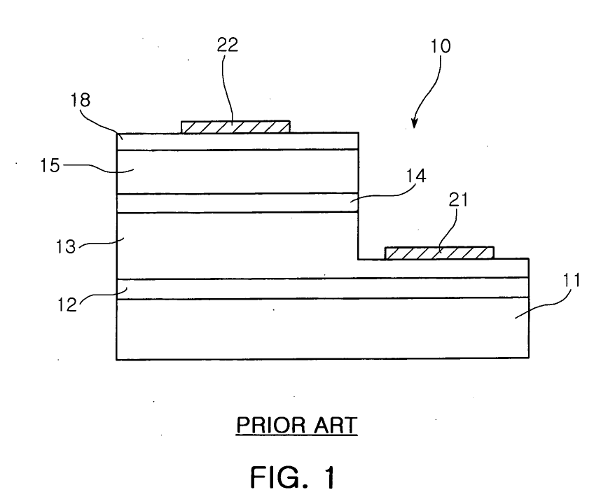

FIG. 2 is a graph showing transmittance of various materials of a transparent electrode;

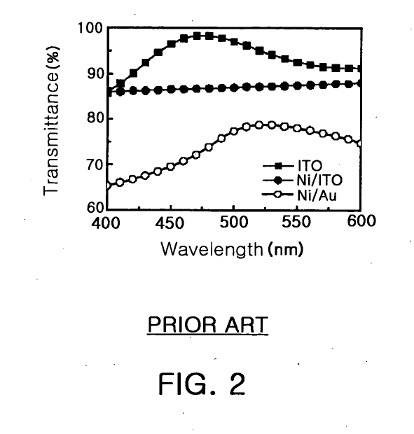

FIG. 3 is a sectional view illustrating a nitride semiconductor light emitting device according to an embodiment of the present invention;

FIG. 4 is a graph showing the specific resistance, carrier mobility and carrier density of an ITO layer according to oxygen partial pressure during formation of the ITO layer according to an embodiment of the present invention;

FIG. 5 is a graph illustrating the sheet resistance and transmittance distribution of an ITO multi-layer according to an embodiment of the present invention;

FIG. 6 is a graph illustrating the sheet resistance distribution of an ITO multi-layer according to another embodiment of the present invention;

FIG. 7 is a graph illustrating the sheet resistance distribution of an ITO multi-layer according to further another embodiment of the present invention; and

FIG. 8 is a sectional view illustrating a nitride semiconductor light emitting device according to another embodiment of the present invention.

### DETAILED DESCRIPTION OF THE PREFERRED EMBODIMENT

Preferred embodiments of the present invention will now be described in detail with reference to the accompanying drawings. The invention may however be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions are exaggerated for clarity and the same reference numerals are used throughout to designate the same components.

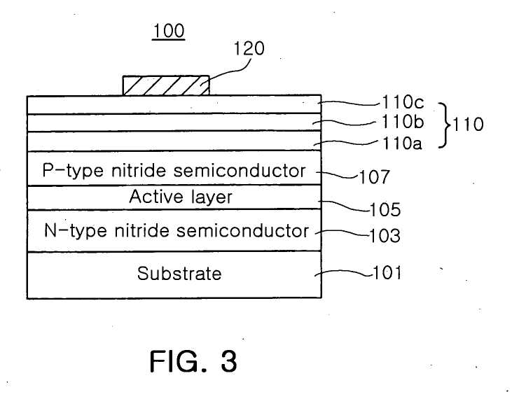

FIG. 3 is a sectional view illustrating a nitride semiconductor light emitting device according to an embodiment of the present invention. Referring to FIG. 3, the nitride semiconductor light emitting device 100 includes an n-type nitride semiconductor layer 103, an active layer 105 and a p-type nitride semiconductor layer 107 sequentially formed on a substrate 101 made of sapphire, etc. On the p-type nitride semiconductor layer 107, a transparent conductive oxide multi-layer 110 composed of a plurality of transparent conductive oxide layers 110a, 110b and 110c is formed. And a p-electrode pad 120 is formed on a top of the transparent conductive oxide multi-layer 110. An n-electrode is not shown for the sake of convenience in description.

The transparent conductive oxide multi-layer 110 may be made of, for example, at least one selected from a group consisting of ITO, ZnO, MgO and InO. In particular, ITO which has a very high light transmittance is preferable.

The plurality of transparent conductive oxide layers constituting the transparent conductive oxide multi-layer 110, have different levels of electric conductivity. Formed with the transparent conductive oxide layers having different levels of electric conductivity, the multi-layer 110 has a function of spreading current. That is, even though the current is applied through the p-side electrode pad 120 having such a narrow area, the current is effectively spread sideward through the multi-layer 110.

Due to such a current spreading effect, the current enters a larger area of the active layer. Thereby, the light emission efficiency is increased and the operating voltage is lowered. In addition, due to the current spreading effect of the stacked structure of oxide layers having different levels of electric conductivity, i.e., the multi-layer 110, the current concentration is suppressed. This reduces the damage from external ESD. Therefore, the light emitting device has further improved resistance to ESD.

The levels of electric conductivity of the transparent conductive oxide layers 110a, 110b and 110c can be adjusted by the oxygen vacancy density existing in each layer. The oxygen vacancy in the transparent conductive oxide layers serve to supply charged carriers. Therefore, with high oxygen vacancy density of the oxide layers 110a to 110c, the carrier density increases, which in turn increases electric conductivity.

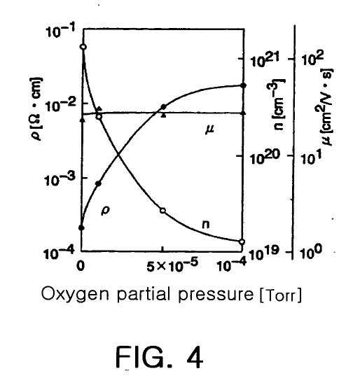

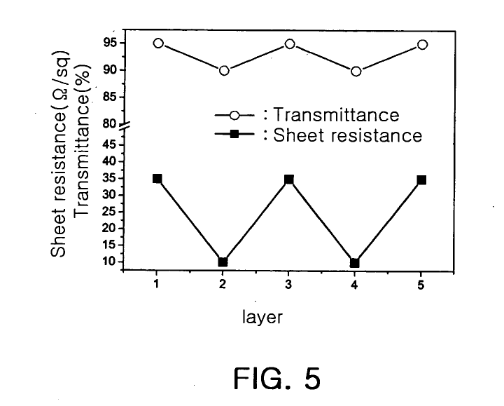

The oxygen vacancy density of the transparent conductive oxide layers 110a to 110c can be adjusted by the oxygen partial pressure during the formation of the transparent conductive oxide layers 110a to 110c. That is, by increasing the oxygen partial pressure when the transparent conductive oxide layers are formed, the density of the oxygen vacancy in the layers can be decreased. FIG. 4 is a graph illustrating the specific resistance (ρ), carrier mobility (μ) and carrier density (n) of the ITO layer according to the oxygen partial pressure during the formation of the ITO layer. As shown in FIG. 4, with the higher oxygen partial pressure, the specific resistance increases (i.e., the electric conductivity decreases), and the carrier density decreases. That is because, with the higher oxygen partial pressure, the oxygen vacancy decreases. The carrier mobility is almost constant irrespective of the oxygen partial pressure; In general, with the high oxygen partial pressure during the formation of the ITO layer, the electric conductivity of the ITO layer decreases but the transparency or transmittance (transmission ratio) of the ITO layer increases (see graphs in FIGS. 4 and 5).

The levels of electric conductivity of the transparent conductive oxide layers 110a, 110b and 110c can be adjusted by varying the composition. For example, the level of conductivity of the ITO layer can be adjusted by changing the content of Sn which is a constituent element of the ITO layer.

The number of layers of the transparent conductive oxide layers 110a to 110c included in the multi-layer 110 is not limited as long as it is two or more. For example, the transparent conductive oxide multi-layer 110 may be formed to consist of a plurality of layer groups stacked at least two times, with each group composed of two layers of transparent conductive oxide layers having different levels of electric conductivity.

Preferably, the oxide layers 110a to 110c constituting the multi-layer 110 may include a stacked structure consisting of high-conductivity, low-conductivity and high-conductivity layer or a stacked structure consisting of low-conductivity, high-conductivity and low-conductivity layers. By alternating the relatively high- and low-conductivity oxide layers as described above, the current spreading effect of the multi-layer 110 becomes greater. Such an example of a multi-layer configuration is shown in the graph in FIG. 5. Referring to FIG. 5, the ITO multi-layer includes 5 layers of ITO layers (see horizontal axis in FIG. 5) including a low-conductivity layer (a first layer), a high-conductivity layer (a second layer), a low-conductivity layer (a third layer), a high-conductivity layer (a fourth layer), a low-conductivity layer (a fifth layer).

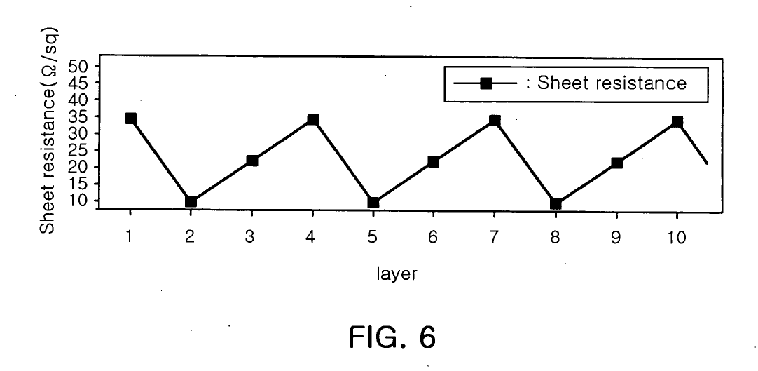

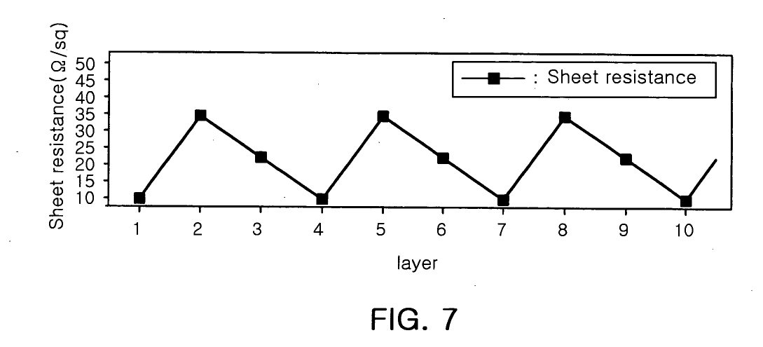

FIGS. 6 and 7 are graphs showing the sheet resistance distribution of the ITO multi-layer according to another embodiment of the present invention. Referring to FIG. 6, the ITO multi-layer includes a plurality of three-layer structures stacked repeatedly with each structure consisting of first, second and third layers (the second layer has a higher level of conductivity than the first and third layers, and the first and third layers have different levels of conductivity). In FIG. 6, the sheet resistance of the first layer is higher than that of the third layer, but conversely, the first layer may be configured to have lower sheet resistance than the third layer.

With reference to FIG. 7, the ITO multi-layer includes a plurality of three-layer structures stacked repeatedly with each structure consisting of first, second and third layers (the second layer has a higher level of conductivity than the first and third layer, and the first and third layers have different levels of conductivity). In FIG. 7, the sheet resistance of the first layer is lower than that of the third layer, but conversely, the first layer may be configured to have higher sheet resistance than that of the third layer.

As described above, the three-layer structures with each layer having different level of conductivity are stacked repeatedly to form the ITO multi-layer, preventing concentration of current in some region while realizing a substantially large light emission area. This improves uniformity of light emission, operating voltage characteristics, and resistance to ESD.

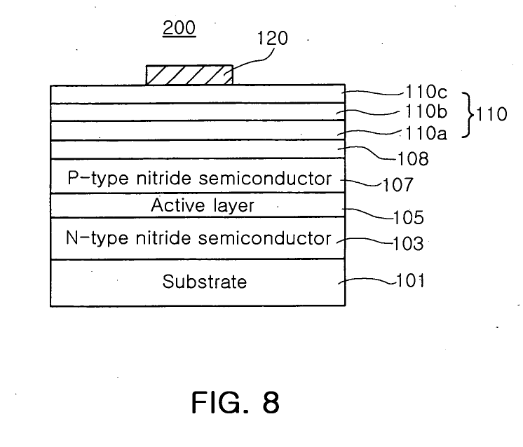

FIG. 8 is a sectional view illustrating a nitride semiconductor light emitting device according to another embodiment of the present invention. Referring to FIG. 8, except for additionally including a contact metal layer 108 between the p-type nitride semiconductor layer 107 and the transparent conductive oxide multi-layer 110, the nitride semiconductor light emitting device 200 has the same configuration as the previously described light emitting device 100. The contact metal layer 108 functions to further improve the ohmic contact characteristics with the p-type nitride semiconductor layer. The contact metal layer 108 may be made of, for example, at least one selected from a group consisting of Ni, Au, Pt and Pd.

Next, a manufacturing method of the nitride semiconductor light emitting device according to the present invention is explained hereunder. The manufacturing method according to the present invention can be applied to a horizontal type light emitting device with the n-electrode and the p-electrode disposed at the same side as well as a vertical type light emitting device with the n-electrode and the p-electrode disposed oppositely.

First, an n-type semiconductor layer 103, an active layer 105 and a p-type semiconductor layer 107 are grown on a substrate 101 such as a sapphire substrate via MOCVD, HVPE and the like (see FIG. 3). In order to obtain high-quality nitride semiconductor crystals, it is preferable to form a buffer layer on the substrate 101 before forming the n-type semiconductor layer 103. Then, a transparent conductive oxide multi-layer 110 described above is formed using, for example, reactive sputtering. That is, transparent conductive oxide layers 110a to 110c having different levels of electric conductivity are deposited. At this time, the transparent conductive oxide layers 110a to 110c may be configured to have different oxygen partial pressures or compositions (e.g., Sn content when depositing the ITO layer) to vary the levels of conductivity of the oxide layers. Thereafter, a p-electrode pad 120 is formed on the transparent conductive oxide multi-layer 110.

For superior ohmic contact, a contact metal layer 108 made of at least one selected from a group consisting of Ni, Au, Pt and Pd may be formed on the p-type nitride semiconductor layer 107 before depositing the transparent conductive oxide multi-layer 110 (see FIG. 8). In order to further enhance the current spreading effect, a relatively high- and low-conductivity oxide layers may be alternately stacked to form the multi-layer 110 (see FIG. 5).

According to the present invention set forth above, transparent conductive oxide layers having different levels of conductivity are stacked on a p-type nitride semiconductor layer to ensure a current spreading effect. Thereby, light emission efficiency is enhanced while operating voltage is lowered and resistance to ESD is improved.

While the present invention has been shown and described in connection with the preferred embodiments, it will be apparent to those skilled in the art that modifications and variations can be made without departing from the spirit and scope of the invention as defined by the appended claims.

What is claimed is:

1. A nitride semiconductor light emitting device comprising:
an n-type nitride semiconductor layer, an active layer and a p-type nitride semiconductor layer sequentially formed on a substrate; and
a transparent conductive oxide multi-layer formed on the p-type nitride semiconductor layer,
wherein the transparent conductive oxide multi-layer includes two or more transparent conductive oxide layers having different levels of conductivity.

2. The nitride semiconductor light emitting device according to claim 1, wherein the transparent conductive oxide layers are made of at least one selected from a group consisting of ITO, ZnO, MgO and InO.

3. The nitride semiconductor light emitting device according to claim 1, wherein the transparent conductive oxide layers have different oxygen vacancy densities.

4. The nitride semiconductor light emitting device according to claim 1, wherein the transparent conductive oxide layers have different compositions.

5. The nitride semiconductor light emitting device according to claim 1, wherein the transparent conductive oxide layers comprise ITO layers having different Sn contents.

6. The nitride semiconductor light emitting device according to claim 1, wherein the transparent conductive oxide multi-layer comprises a plurality of layer groups stacked repeatedly two or more times, each of the layer groups consisting of two or more transparent conductive oxide layers having different levels of conductivity.

7. The nitride semiconductor light emitting device according to claim 1, wherein the transparent conductive oxide multi-layer includes a stacked structure of first, second and third oxide layers, and
the second oxide layer has a lower level of conductivity than the first and third oxide layers.

8. The nitride semiconductor light emitting device according to claim 1, wherein the transparent conductive oxide multi-layer includes a stacked structure of first, second and third oxide layers, and
the second oxide layer has a higher level of conductivity than the first and third oxide layers.

9. The nitride semiconductor light emitting device according to claim 1, wherein the transparent conductive oxide multi-layer comprises a plurality of three-layer structures stacked repeatedly, each of the three-layer structures having first, second and third oxide layers, and
the second oxide layer has a lower level of conductivity than the first and third oxide layer, and the first and third layers have different levels of conductivity from each other.

10. The nitride semiconductor light emitting device according to claim 1, wherein the transparent conductive oxide multi-layer comprises a plurality of three-layer structures stacked repeatedly, each of the three-layer structures having first, second and third oxide layers, and
the second oxide layer has a higher level of conductivity than the first and third oxide layers, and the first and third oxide layers have different levels of conductivity from each other.

11. The nitride semiconductor light emitting device according to claim 1, further comprising a contact metal layer between the p-type nitride semiconductor layer and the transparent conductive oxide multi-layer.

12. The nitride semiconductor light emitting device according to claim 11, wherein the contact metal layer is made of at least one selected from a group consisting of Ni, Au, Pt and Pd.

13. A method of manufacturing a nitride semiconductor light emitting device comprising steps of:
sequentially forming an n-type nitride semiconductor layer, an active layer and a p-type nitride semiconductor layer on a substrate; and
forming a transparent conductive oxide multi-layer which includes two or more transparent conductive oxide layers having different levels of conductivity on the p-type nitride semiconductor layer.

14. The method according to claim 13, wherein the transparent conductive oxide layers are made of at least one selected from a group consisting of ITO, ZnO, MgO and InO.

15. The method according to claim 13, wherein the step of forming the transparent conductive oxide multi-layer comprises forming the transparent conductive oxide layers having different oxygen vacancy densities.

16. The method according to claim 15, wherein the oxygen vacancy density is adjusted by oxygen partial pressure at the time of forming the transparent conductive oxide layers.

17. The method according to claim 13, wherein the step of forming the transparent conductive oxide multi-layer comprises forming the transparent conductive oxide layers having different compositions.

18. The method according to claim 13, wherein the step of forming the transparent conductive oxide multi-layer comprises forming ITO layers having different Sn contents as the transparent conductive oxide layers.

19. The method according to claim 13, wherein the step of forming the transparent conductive oxide multi-layer comprises forming a stacked structure of first, second and third oxide layers, where the second oxide layer has a lower level of conductivity than the first and third oxide layers.

20. The method according to claim 13, wherein the step of forming the transparent conductive oxide multi-layer comprises forming a stacked structure of first, second and third oxide layers, where the second oxide layer has a higher level of conductivity than the first and third oxide layers.

21. The method according to claim 13, wherein the step of forming the transparent conductive oxide multi-layer comprises repeatedly stacking a plurality of three-layer structures each consisting of first, second and third oxide layers, where the second oxide layer has a lower level of conductivity than the first and third oxide layers, and the first and third oxide layers have different levels of conductivity from each other.

22. The method according to claim 13, wherein the step of forming the transparent conductive oxide multi-layer comprises repeatedly stacking a plurality of three-layer structures each consisting of first, second and third oxide layers, where the second oxide layer has a higher level of conductivity than the first and third oxide layers, and the first and third oxide layers have different levels of conductivity from each other.

23. The method according to claim 13, further comprising forming a contact metal layer on the p-type nitride semiconductor layer before the step of forming the transparent conductive oxide multi-layer.

24. The method according to claim 23, wherein the contact metal layer is made of at least one selected from a group consisting of Ni, Au, Pt and Pd.
